(19) United States
(12) Patent Application Publication
(10) Pub. No.: US 2025/0047066 A1
(43) Pub. Date: Feb. 6, 2025

(54) SURFACE EMITTING SEMICONDUCTOR LASER AND METHOD FOR PRODUCING A SURFACE EMITTING SEMICONDUCTOR LASER

(71) Applicant: ams-OSRAM International GmbH, Regensburg (DE)

(72) Inventors: Hubert HALBRITTER, Dietfurt (DE); Bruno JENTZSCH, Regensburg (DE); Adrian Stefan AVRAMESCU, Regensburg (DE); Laura KREINER, Regensburg (DE); Lutz HÖPPEL, Alteglofsheim (DE); Christoph EICHLER, Donaustauf (DE)

(73) Assignee: ams-OSRAM International GmbH, Regensburg (DE)

(21) Appl. No.: 18/707,226

(22) PCT Filed: Nov. 2, 2022
(86) PCT No.: PCT/EP2022/080527

§ 371 Date: May 3, 2024

(30) Foreign Application Priority Data
Nov. 5, 2021 (DE) 102021128854.1

(51) Int. Cl. H01S 5/11; H01S 5/183; H01S 5/343

(52) U.S. Cl. CPC H01S 5/11; H01S 5/18305; H01S 5/18386; H01S 5/34333

(57) ABSTRACT

A surface emitting semiconductor laser is disclosed that includes a semiconductor layer sequence having an active layer for generating laser radiation, a carrier substrate on one side of the semiconductor layer sequence, and an optical structure for influencing at least one degree of freedom of the laser radiation. The carrier substrate is different from a growth substrate of the semiconductor layer sequence and the growth substrate is at least partly removed. The optical structure has a varying refractive index in a lateral direction for the laser radiation.

### CROSS-REFERENCE TO RELATED APPLICATIONS

The present application is a national stage entry from International Application No. PCT/EP2022/080527, filed on Nov. 2, 2022, published as International Publication No. WO 2023/078912 A1 on May 11, 2023, and claims priority to German Patent Application No. 10 2021 128 854.1, filed Nov. 5, 2021, the disclosures of all of which are hereby incorporated by reference in their entireties.

### FIELD

A surface-emitting semiconductor laser is disclosed. In addition, a method of manufacturing a surface-emitting semiconductor laser is disclosed.

### BACKGROUND

One task to be solved is to provide an improved surface-emitting semiconductor laser, for example a surface-emitting semiconductor laser with predetermined emission properties. Another task to be solved is to specify a method for manufacturing such a semiconductor laser.

These tasks are solved, inter alia, by the subjects of the independent claims. Advantageous embodiments and further developments are the subject of the dependent claims and are further apparent from the following description and the figures.

### SUMMARY

First, the surface-emitting semiconductor laser is specified.

According to at least one embodiment, the surface-emitting semiconductor laser, hereinafter also referred to simply as a semiconductor laser, comprises a semiconductor layer sequence with an active layer for generating laser radiation. The laser radiation is generated in the active layer, in particular by recombination of electrons and holes. The laser radiation can be laser radiation in the visible range, in the UV range or in the IR range.

The semiconductor layer sequence is based, for example, on a III-V compound semiconductor material. The semiconductor material is, for example, a nitride compound semiconductor material, such as AlₙIn₁₋ₙ₋ₘGaₘN, or a phosphide compound semiconductor material, such as AlₙIn₁₋ₙ₋ₘGaₘP, or an arsenide semiconductor compound material, such as AlₙIn₁₋ₙ₋ₘGaₘAs or AlₙIn₁₋ₙ₋ₘGaₘAsP, where 0≤n≤1, 0≤m≤1 and m+n≤1. The semiconductor layer sequence may comprise dopants and additional components. For the sake of simplicity, however, only the essential components of the crystal lattice of the semiconductor layer sequence, i.e. Al, As, Ga, In, N or P, are specified, even if these may be partially replaced and/or supplemented by small amounts of other substances.

The active layer of the semiconductor layer sequence includes, in particular, at least one p-n junction and/or at least one quantum well structure in the form of a single quantum well, SQW for short, or in the form of a multi-quantum well structure, MQW for short. For example, the semiconductor layer sequence comprises one, in particular exactly one, contiguous, in particular simply connected, active layer.

The semiconductor laser can comprise several pixels that can be controlled individually and independently of each other, for example. Each pixel can be uniquely assigned a contiguous semiconductor layer sequence with an active layer as described above. The individual pixels with the associated semiconductor layer sequence can be generated by segmenting an originally contiguous semiconductor layer sequence. All pixels can be arranged on the same carrier substrate.

A surface-emitting semiconductor laser, for example VCSEL (vertical-cavity surface-emitting laser) or PCSEL (photonic crystal surface-emitting laser), emits the laser radiation in a direction transverse or perpendicular to a main extension plane of the active layer. A semiconductor laser is also known as a laser diode. In particular, the semiconductor laser can be a semiconductor chip.

According to at least one embodiment, the semiconductor laser comprises a carrier substrate on one side of the semiconductor layer sequence. The carrier substrate is in particular the substrate carrying the semiconductor layer sequence. The carrier substrate is self-supporting, for example. The carrier substrate can be the only self-supporting element of the semiconductor laser.

The fact that an element, for example a layer or a substrate, is arranged or applied “on” or “over” another element can mean here and in the following that the one element is arranged directly, i.e. in direct mechanical and/or electrical contact, on the other element. Furthermore, it can also mean that the element is arranged indirectly on or over the other element. Further elements, such as layers, can then be arranged between one element and the other.

According to at least one embodiment, the semiconductor laser comprises an optical structure for influencing at least one degree of freedom of the laser radiation. In particular, the influencing is targeted or predetermined. This means that the optical structure is designed by purpose to influence the laser radiation. The optical structure is therefore preferably not a randomly created structure.

The degree of freedom of the laser radiation can be a beam direction, for example measured with respect to the normal to the main extension plane of the active layer. For example, the angle between the beam direction and the normal can be set by means of the optical structure, for example anywhere between 0° and 60° inclusive. The degree of freedom of the laser radiation can alternatively or additionally also be a wavelength of the laser radiation so that the optical structure forms a wavelength filter.

For example, the optical structure is arranged close to the active layer, for example at a distance from the active layer that is at most 5 times as large or at most twice as large or at most as large or at most half as large as the thickness of the semiconductor layer sequence. The optical structure is arranged, for example, between the active layer and an electrical contact element of the semiconductor laser.

According to at least one embodiment, the carrier substrate is different from a growth substrate of the semiconductor layer sequence. The growth substrate may be partially or completely removed. Any remainders of the growth substrate are not sufficient, for example, to mechanically stabilize the semiconductor layer sequence. For example, any remainder of the growth substrate is not self-supporting. In other words, the semiconductor laser is a thin film semiconductor laser.

According to at least one embodiment, the optical structure comprises a refractive index for the laser radiation that varies in lateral direction, i.e. parallel to the main extension plane of the active layer and/or parallel to the main extension plane of the semiconductor layer sequence. The variation in the refractive index is predetermined or specifically designed.

For example, the optical structure comprises a plurality of regions having different refractive indices, these regions being arranged laterally adjacent to each other. For example, the optical structure comprises at least two or at least three or at least four regions with each two regions having different refractive indices. The regions can be arranged laterally and/or vertically next to each other. This group of at least two or at least three or at least four areas arranged next to each other can then be arranged repeatedly one behind the other in the lateral direction. The optical structure may comprise a periodic or aperiodic variation of the refractive index in the lateral direction. The optical structure can be one-dimensional, two-dimensional or three-dimensional. In other words, the refractive index can vary, e.g. periodically, in one lateral direction or in two orthogonal lateral directions or in two orthogonal lateral directions and one direction perpendicular to the main extension plane of the active layer.

Two regions of different refractive index differ here and in the following in their refractive index preferably by at least 5% or at least 10% or at least 30%. The refractive index refers here and in the following to the wavelength of the laser radiation.

In at least one embodiment, the surface-emitting semiconductor laser comprises a semiconductor layer sequence with an active layer for generating a laser radiation, a carrier substrate on one side of the semiconductor layer sequence and an optical structure for influencing at least one degree of freedom of the laser radiation. The carrier substrate is different from a growth substrate of the semiconductor layer sequence and the growth substrate is at least partially removed. The optical structure comprises a refractive index for the laser radiation that varies in the lateral direction.

The present invention is based, inter alia, on the realization that, in order to achieve high efficiency, the optical structure of surface-emitting semiconductor lasers with optical structures should be formed as close as possible to the active layer. Forming the optical structure between the growth substrate and the active layer can be problematic, as high defect densities can then occur in the subsequently produced active layer. Forming the optical structure on a side of the active layer facing away from the growth substrate (usually the p-doped region of the semiconductor layer sequence) can also lead to many defects in the active layer.

The inventors had, inter alia, the idea of using a thin-film process, in which the growth substrate is removed and replaced by a carrier substrate, to make the semiconductor area originally located between the growth substrate and the active layer accessible. An optical structure can be generated at or in this area in the immediate vicinity of the active layer without the risk of excessive defect densities in the active layer.

According to at least one embodiment, the active layer is arranged between the carrier substrate and the optical structure. For example, semiconductor material of the semiconductor layer sequence is n-conducting between the optical structure and the active layer. Alternatively, the optical structure can also be arranged between the carrier substrate and the active layer. For example, semiconductor material of the semiconductor layer sequence between the optical structure and the active layer is then p-conducting.

According to at least one embodiment, the optical structure comprises electrically conductive material, for example semiconductor material. The electrically conductive material of the optical structure can transport charge carriers to the active layer during operation of the semiconductor laser.

According to at least one embodiment, laser radiation is coupled out of the semiconductor laser via a radiation exit surface during operation. For example, at least 90% or at least 99% of the total radiation coupled out of the semiconductor laser is coupled out via the radiation exit surface. The semiconductor layer sequence with the active layer can be arranged between the carrier substrate and the radiation exit surface.

According to at least one embodiment, the optical structure comprises or consists of a photonic crystal. The structure dimensions in the photonic crystal are, for example, equal to or greater than a quarter of the wavelength of the laser radiation. The semiconductor laser is, for example, a so-called surface-emitting photonic crystal laser, or PCSEL.

According to at least one embodiment, the optical structure is at least partially formed by the semiconductor material of the semiconductor layer sequence. The optical structure can be partially or completely formed in the semiconductor layer sequence or integrated into the semiconductor layer sequence. In particular, this means that the optical structure is at least partially formed by the semiconductor material that was grown on the growth substrate for the semiconductor layer sequence, for example by epitaxial growth. The semiconductor material of the optical structure is therefore already present before the removal of the growth substrate. The skilled person can recognize this, for example, by the fact that the semiconductor material of the optical structure has grown with few defects and/or is crystalline.

According to at least one embodiment, the optical structure is formed at least partially, i.e. partially or completely, by transparent conductive oxide, such as indium tin oxide, ITO for short. For example, the optical structure then comprises regions of semiconductor material of the semiconductor layer sequence and transparent conductive oxide arranged alternately in the lateral direction or regions of different transparent conductive oxides arranged alternately in the lateral direction. At least some of the regions made of these different materials preferably lie in a plane, for example a plane parallel to the main extension plane of the active layer. The different materials preferably have different refractive indices for the laser radiation.

In the following, transparent conductive oxide is also referred to as TCO for short, as a short form of transparent conducting oxide.

According to at least one embodiment, the TCO is used for the current impression in the semiconductor layer sequence. For example, the TCO is in direct contact with the semiconductor layer sequence. During operation, for example, charge carriers are injected into the TCO starting from a metallic contact element and from there transferred to the semiconductor layer sequence, where they then recombine within the active layer. The TCO can be used to conduct electrons and/or holes.

For example, the active layer is arranged between the TCO and the carrier substrate. Alternatively, the TCO can be arranged between the carrier substrate and the active layer.

According to at least one embodiment, the optical structure is at least partially formed by dielectric material. For example, the optical structure comprises regions of dielectric material and regions of semiconductor material and/or of TCO, which are arranged alternately in the lateral direction. At least some regions of dielectric material and at least some regions of the other material preferably lie in a plane, for example a plane parallel to the main extension plane of the active layer. The refractive index of the dielectric material differs, for example, from that of the semiconductor material and/or from that of the TCO. The dielectric material can be SiO₂.

According to at least one embodiment, the optical structure comprises a plurality of cavities. The cavities can be gas-filled. The cavities are arranged one behind the other in lateral direction, for example. For example, several cavities lie in a plane, for example a plane parallel to the main extension plane of the active layer. The regions between the cavities preferably comprise a different refractive index than the cavities. For example, the regions in between are formed by semiconductor material and/or dielectric material and/or TCO. The expansion of the cavities is preferably at least λ/4 in each case, where λ is the wavelength of the laser radiation.

The cavities can be formed entirely in the semiconductor layer sequence, i.e. delimited exclusively by semiconductor material. Alternatively, the cavities can be formed entirely in TCO, i.e. delimited exclusively by TCO. It is also possible for the cavities to be formed entirely in dielectric material, and accordingly delimited exclusively by dielectric material. However, it is also possible that the cavities extend over at least two material systems, for example semiconductor material and TCO or semiconductor material and dielectric material or TCO and dielectric material, and are accordingly delimited by at least two of these material systems.

According to at least one embodiment, an electrically insulating structure is provided in the edge region of the semiconductor layer sequence to reduce a current impression in the semiconductor layer sequence. In the region of the electrically insulating structure, the generation of laser radiation can at least be suppressed, for example completely suppressed. The electrically insulating structure defines an aperture, for example. The electrically insulating structure then delimits the aperture, in particular in the lateral direction. For example, laser radiation is only generated and/or decoupled from the semiconductor laser in the area of the aperture. The electrically insulating structure is arranged around the aperture, for example. A lateral expansion of the aperture or its diameter is preferably at least 10 nm or at least 40 nm and/or at most 200 nm and/or at most 150 nm. The aperture can be circular.

Herein, the edge region of the semiconductor layer sequence is a region adjacent to side surfaces or mesa edges of the semiconductor layer sequence.

The electrically insulating structure can be formed by dielectric material, for example by the same dielectric material as the optical structure. Alternatively, the electrically insulating structure can also be formed by electrically inactivated semiconductor material, for example by plasma-etched semiconductor material of the semiconductor layer sequence. The electrically insulating structure can also be formed by a metal oxide and generated by oxidation of a metal-containing layer in the semiconductor laser. The metal can be aluminum. The metal-containing layer may be part of the semiconductor layer sequence and/or the Bragg mirror. For example, the metal-containing layer is AlAs.

According to at least one embodiment, the electrically insulating structure is arranged at the same height as the optical structure with respect to the active layer. This means that a plane through the electrically insulating structure parallel to the main extension plane of the active layer runs at least partially through the optical structure or its regions of different refractive indices. The vertical expansion of the electrically insulating structure, measured perpendicular to the main extension plane of the active layer, can essentially, for example up to ±5%, correspond to the vertical expansion of the optical structure.

However, the electrically insulating structure can also be arranged at a different height than the optical structure with respect to the active layer, for example on a different side of the active layer than the optical structure.

According to at least one embodiment, a Bragg mirror is arranged between the carrier substrate and the active layer. The Bragg mirror comprises several layers of different refractive indices arranged one above the other. One above the other means one after the other in a direction perpendicular to the main extension plane of the active layer. The Bragg mirror may comprise a periodic arrangement of the layers. The layers of the Bragg mirror are made of semiconductor material, for example. Then, for example, the Bragg mirror is part of the semiconductor layer sequence. For example, the Bragg mirror may comprise porous semiconductor material, such as porous GaN. Alternatively, the layers of the Bragg mirror can be formed from dielectric material. The Bragg mirror is then in particular a dielectric mirror.

According to at least one embodiment, the semiconductor layer sequence is based on AlₙIn₁₋ₙ₋ₘGaₘN or AlₙIn₁₋ₙ₋ₘGaₘAs with 0≤n≤1, 0≤m≤1 and m+n≤1. According to at least one embodiment, the semiconductor layer sequence comprises a p-conducting layer between the active layer and the carrier substrate or is completely p-conducting in this region. On the other side of the active layer, the semiconductor layer sequence may comprise an n-conducting layer or be completely n-conducting there.

According to at least one embodiment, the carrier substrate comprises or consists of one or more of the following materials: Si, Ge, ceramic, AlN, SiC, sapphire.

According to at least one embodiment, the semiconductor laser comprises a further optical structure in addition to the optical structure. The further optical structure also comprises, for example, a refractive index that varies in the lateral direction. All features disclosed in connection with the optical structure are accordingly also disclosed for the further optical structure. In particular, the further optical structure may also be a photonic crystal.

According to at least one embodiment, the further optical structure is arranged on a different side of the active layer than the optical structure. For example, the further optical structure is arranged between the carrier substrate and the active layer.

Alternatively, the optical structure and the further optical structure can also be arranged on the same side of the active layer, but preferably then at different heights with respect to the main extension plane of the active layer.

By using two optical structures at different heights, the laser radiation can be influenced very individually and precisely. Two optical structures at different heights are easier to manufacture than one optical structure with the same optical properties.

According to at least one embodiment, a metal layer is arranged between the carrier substrate and the semiconductor layer sequence. The metal layer is preferably reflective for the laser radiation. For example, the metal layer is arranged between the Bragg mirror and the carrier substrate. For example, the metal layer comprises one or more of the following materials: Al, Au, Ag, Pd, Ti, Pt, Ni. During operation, the metal layer can transport charge carriers towards the semiconductor layer sequence.

The semiconductor laser described here can be used in a headlight, for example in a motor vehicle. The semiconductor laser can be used in the field of AR/VR, material processing, sensor technology and/or Lidar.

Next, the method of manufacturing a surface-emitting semiconductor laser is disclosed. The method is particularly suitable for manufacturing a semiconductor laser according to at least one of the embodiments described herein. All features disclosed in connection with the surface-emitting semiconductor laser are therefore also disclosed for the method and vice versa.

According to at least one embodiment, the method comprises a step in which a semiconductor layer sequence with an active layer is grown on a growth substrate. The active layer is configured to generate laser radiation. The growth substrate is, for example, a GaN substrate or a GaAs substrate.

According to at least one embodiment, the method comprises a step in which a carrier substrate is applied to a side of the semiconductor layer sequence facing away from the growth substrate. The carrier substrate can be connected to the semiconductor layer sequence by a bonding process, for example soldering or adhesion.

According to at least one embodiment, the method comprises a step in which the growth substrate is at least partially, in particular completely, removed from the semiconductor layer sequence.

According to at least one embodiment, the method comprises a step of forming an optical structure on one side of the semiconductor layer sequence. The optical structure may comprise a refractive index for the laser radiation that varies in a lateral direction, perpendicular to the growth direction of the semiconductor layer sequence.

The first three steps of the method are preferably carried out one after the other in the order indicated. The step of forming the optical structure can take place after the removal of the growth substrate. The optical structure is then formed in particular on a side of the active layer opposite the carrier substrate.

Alternatively, the optical structure can also be formed before the carrier substrate is applied. For example, the optical structure is formed during the growth of the semiconductor layer sequence or after the growth of the semiconductor layer sequence. The optical structure is then formed, for example, on a side of the active layer facing away from the growth substrate.

An optical structure can also be formed on a side of the active layer facing away from the carrier substrate and another optical structure can be formed on a side of the active layer facing away from the growth substrate.

For example, an etching process can be used to remove the growth substrate. For this purpose, a sacrificial layer can be formed between the semiconductor layer sequence and the growth substrate, which is destroyed by etching and thus the semiconductor layer sequence can be separated from the growth substrate. The sacrificial layer is, for example, highly doped n-GaN.

The growth substrate can also be removed by grinding. This can also be used for homoepitaxial growth, for example a GaN semiconductor layer sequence on a GaN substrate. Here, particular attention should be paid to the stress balance so that the semiconductor laser is not impaired by cracks.

Therefore, it is preferable to use a carrier substrate whose thermal expansion coefficient is adapted to the rest of the layer stack (e.g. germanium) and a ductile solder system (e.g. AuInSn). The remaining unwanted material can then be removed, for example by a dry- or wet-chemical etching process, which stops on an epitaxially defined etch stop layer.

Another way to remove the growth substrate is epitaxial growth on 2D materials with low adhesion to neighboring layers (only through Van-der-Waals forces). In this way, components can be removed from the growth substrate over a large area or in chips by loosening the weak bond between the layers. Hexagonal boron nitride is particularly suitable for the growth of a GaN-based semiconductor layer sequence. In order to enable good relaxation of stresses in the lateral direction and at the same time simplify the detachment process, growth is only advantageous within predefined areas, for example only on the chip surfaces and not in the separation trenches in between.

By introducing a suitable, absorbent interface and a directly adjacent material with a suitable chemical composition, a laser-based method can also be used to remove the growth substrate (laser lift-off).

According to at least one embodiment, forming the optical structure comprises a step in which the semiconductor layer sequence is structured by introducing a plurality of depressions into the semiconductor layer sequence. This is done, for example, on a side of the semiconductor layer sequence facing away from the active layer. The structuring can be carried out, for example, by means of an etching process using a mask. The mask can be formed from photoresist, SiO, ITO, SiN or metal. A two-stage etching process using two masks can also be used, whereby depressions of different depths can be generated in the semiconductor layer sequence.

The semiconductor layer sequence comprises, for example, an etch stop layer. The etch stop layer is formed, for example, on a side of the active layer facing away from the carrier substrate and within the semiconductor layer sequence. During the etching process to form the depressions, the semiconductor material is then removed up to the etch stop layer.

Instead of using the mask for structuring, the mask can also be overgrown with semiconductor material, whereby the mask becomes part of the optical structure. Overgrowth can create cavities in the semiconductor material, which are part of the optical structure.

In particular, the depressions are introduced into the semiconductor layer sequence grown on the growth substrate. For example, no more semiconductor material is then grown after the removal of the growth substrate and before the insertion of the depressions.

According to at least one embodiment, the formation of the optical structure comprises a step in which the depressions in the semiconductor layer sequence are filled with a TCO and/or a dielectric material. The TCO or the dielectric material preferably comprises a different refractive index than the semiconductor material of the semiconductor layer sequence. The filling creates an optical structure with a refractive index that varies in the lateral direction.

According to one embodiment, forming the optical structure comprises a step in which a TCO is applied to the semiconductor layer sequence. The TCO can be applied via sputtering. For example, the TCO is applied to a side of the semiconductor layer sequence facing away from the growth substrate before the carrier substrate is applied or to a side of the semiconductor layer sequence facing away from the carrier substrate after the growth substrate has been removed. The applied TCO can then initially form a continuous layer.

According to at least one embodiment, forming the optical structure comprises a step in which the TCO is structured by introducing depressions into the TCO. This can be done as described above by a single or multi-stage etching process using at least one mask. The depressions in the TCO can then be filled with a dielectric material and/or a TCO. This can also result in a variation of the refractive index in the lateral direction.

When filling the depressions with TCO, for example, a different sputtering or disposition setting is used than when the TCO was previously applied, which can lead to lateral oversputtering. In particular, this can create cavities in the area of the depressions, which then form part of the optical structure.

According to at least one embodiment, the optical structure in the semiconductor layer sequence is formed by overgrowing structures with semiconductor material. For example, after a first interval of the growth process of the semiconductor layer sequence, a structure made of a material (for example dielectric) other than the material of the semiconductor layer sequence is applied to the previously grown semiconductor material and/or the previously grown semiconductor material is structured. In a subsequent growth interval, this structure is overgrown with semiconductor material, also known as “regrowth”. By overgrowing the structures, cavities can be created in the region of the structures. The other material together with the semiconductor material or the cavities together with the semiconductor material can then form the optical structure with a refractive index that varies in the lateral direction. In the following, a surface-emitting semiconductor laser described herein and a method for manufacturing a surface-emitting semiconductor laser described herein are explained in more detail with reference to drawings on the basis of exemplary embodiments. Identical reference signs indicate identical elements in the individual figures. However, no references to scale are shown; rather, individual elements may be shown in exaggerated size for better understanding. Insofar as elements or components in the various figures correspond in their function, their description is not repeated for each of the following figures. For reasons of clarity, elements may not be provided with corresponding reference signs in all figures.

### BRIEF DESCRIPTION OF THE DRAWINGS

FIGS. 1 to 6 show an exemplary embodiment of the method in various positions and an exemplary embodiment of the surface-emitting semiconductor laser,

FIGS. 7 and 8 show two further exemplary embodiments of the semiconductor laser,

FIGS. 9 to 12 show a further exemplary embodiment of the method in various positions and a further exemplary embodiment of the semiconductor laser,

FIGS. 13 to 17 show a further exemplary embodiment of the method in various positions and a further exemplary embodiment of the semiconductor laser,

FIG. 18 shows another exemplary embodiment of the semiconductor laser,

FIGS. 19 and 20 show a further exemplary embodiment of the method in various positions and a further exemplary embodiment of the semiconductor laser,

FIGS. 21 to 23 show a further exemplary embodiment of the method in various positions and a further exemplary embodiment of the semiconductor laser,

FIGS. 24 to 32 show further exemplary embodiments of the semiconductor laser,

FIG. 33 shows a top view of an exemplary embodiment of a semiconductor laser.

### DETAILED DESCRIPTION

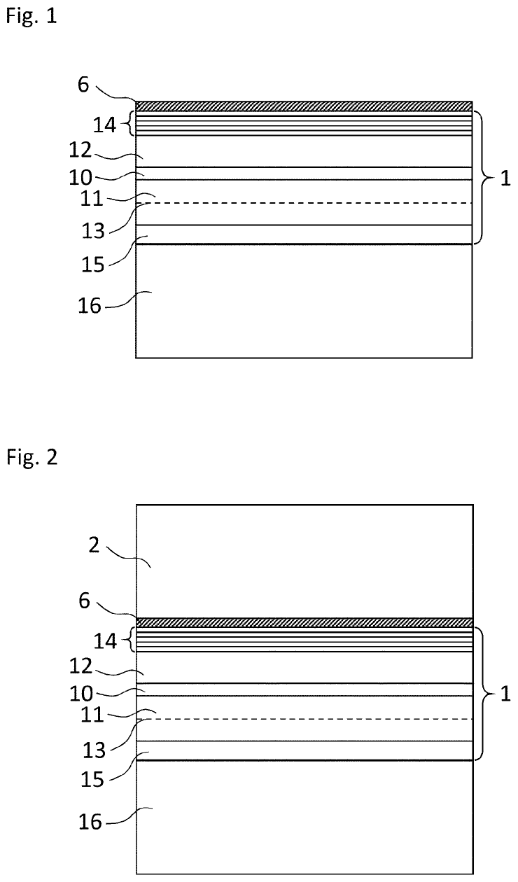

FIG. 1 shows a position in an exemplary embodiment of the method, in which a semiconductor layer sequence 1 is grown on a growth substrate 16. The semiconductor layer sequence 1 is based, for example, on AlInGaN. Alternatively, the semiconductor layer sequence 1 can also be based on AlInGaAs. The growth substrate is, for example, a GaN or GaAs substrate.

The semiconductor layer sequence 1 comprises an active layer 10, an n-conducting layer 11, a p-conducting layer 12, a sacrificial layer 15, an etch-stop layer 13 and a Bragg mirror 14. The Bragg mirror 14 comprises several semiconductor layers of different refractive index. The order in which the various layers are grown over the growth substrate 16 is shown in FIG. 1. A metal layer 6, for example of one or more of the metals selected from Al, Au, Ag, Pd, Ti, Pt, Ni, is arranged on a side of the semiconductor layer sequence 1 facing away from the growth substrate 16.

FIG. 2 shows a later position in the method. A carrier substrate 2 is now applied to the side of the semiconductor layer sequence 1 facing away from the growth substrate 16 or to the metal layer 6, for example by bonding. The carrier substrate 2 comprises or consists of, for example, at least one of the following materials: Si, Ge, ceramic, AlN, SiC, sapphire.

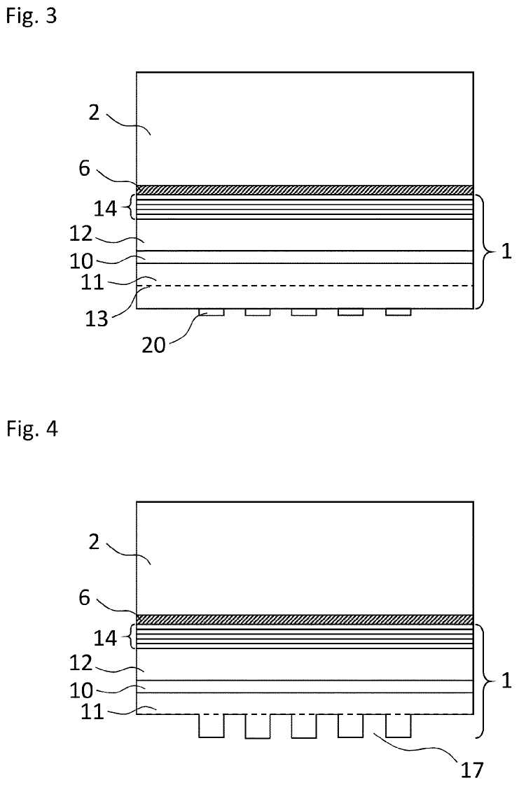

FIG. 3 shows a position in which the growth substrate 16 has been removed from the semiconductor layer sequence 1, for example by an etching process and/or a laser lift-off process and/or a grinding process. The semiconductor layer sequence 1 is now supported and mechanically stabilized by the carrier substrate 2 alone. During the removal of the growth substrate 16, the sacrificial layer 15 is removed.

In addition, a mask 20 made of a photoresist is now applied to the side of the semiconductor layer sequence 1 facing away from the carrier substrate 2. The mask 20 is generated, for example, by photolithography.

FIG. 4 shows a later position after an etching process has been carried out. As a result of the etching process, the semiconductor layer sequence 1 was removed in the regions in which it was not covered by the mask 20 up to the etch stop layer 13. As a result, depressions 17, e.g. trenches or holes, were formed in the semiconductor layer sequence 1, which are arranged periodically or uniformly in the lateral direction. In an edge region of the semiconductor layer sequence 1, the semiconductor layer sequence 1 is also removed up to the etch stop layer 13.

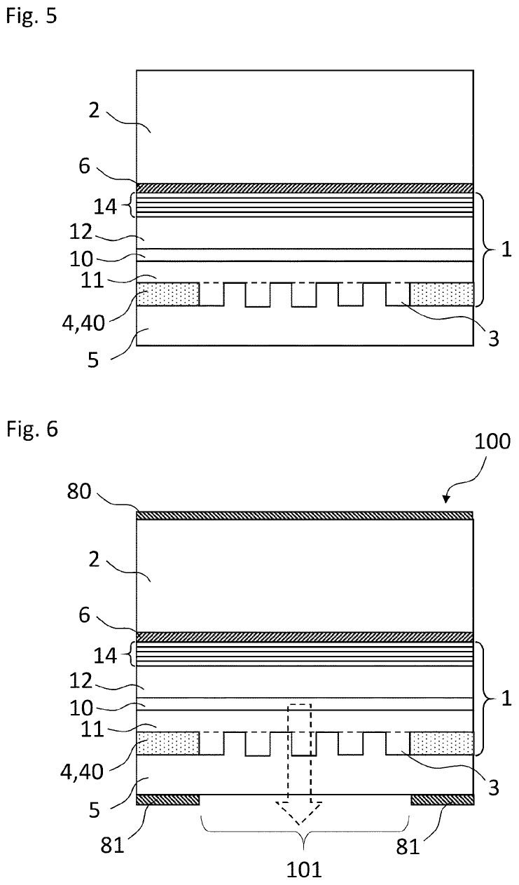

FIG. 5 shows a position in which the edge regions of the semiconductor layer sequence 1, in which the semiconductor layer sequence 1 was previously partially removed, have been covered with an electrically insulating structure 4 made of dielectric material 40. The electrically insulating structure 4 defines an aperture of the semiconductor laser that is subsequently created (see also FIG. 33). The periodically arranged depressions 17 created by the etching process were also filled with a transparent conductive oxide (TCO) 5. The TCO 5 has a different refractive index than the semiconductor material, resulting in an optical structure 3 comprising a refractive index that varies in a lateral direction, parallel to the main extension plane of the active layer 10, and in the present case varies periodically. The optical structure 3 forms, for example, a photonic crystal.

The TCO 5 is also applied to the electrically insulating structure 4 and is further used for electrical contacting of the semiconductor layer sequence 1. Overall, the TCO 5 here forms a continuous layer that extends essentially over the entire lateral expansion of the semiconductor layer sequence 1.

In the position shown in FIG. 6, a contact element 81 is now also applied to the TCO 5. A further contact element 80 is applied to the side of the carrier substrate 2 facing away from the semiconductor layer sequence 1. The two contact elements 80, 81 differ in terms of their polarity during operation of the semiconductor laser 100. FIG. 6 also shows an exemplary embodiment of the surface-emitting semiconductor laser 100.

The carrier substrate 2 is electrically conducting. By electrically contacting the contact elements 80 and 81, charge carriers are injected via the carrier substrate 2 or the TCO 5 into the semiconductor layer sequence 1, where they recombine within the active layer 10. The Bragg mirror 14 is used to direct the laser radiation generated in the active layer 10 (indicated by the dashed arrow) towards the radiation exit surface. The radiation exit surface is opposite the carrier substrate 2. The laser radiation is only emitted in the area of the aperture 101 or, due to the electrically insulating structure 4, laser radiation is only generated in this area. The optical structure 3 influences at least one degree of freedom of the generated laser radiation, for example its beam direction and/or its wavelength.

The thin-film process shown, in which the growth substrate 16 is removed and the region of the semiconductor layer sequence 1 grown between the active layer 10 and the growth substrate 16 is thus made accessible for the formation of an optical structure 3, allows the optical structure 3 to be generated close to the active layer 10 without too many defects in the active layer 10.

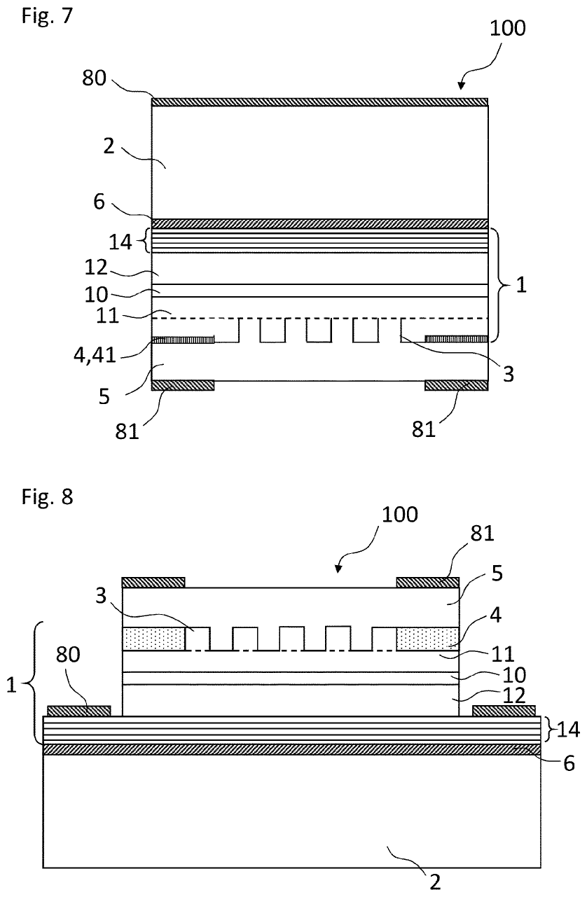

FIG. 7 shows an exemplary embodiment of the semiconductor laser 1 which differs from the exemplary embodiment of FIG. 6 with respect to the electrically insulating structure 4 for forming the aperture. While in FIG. 6 the electrically insulating structure 4 is formed with the help of dielectric material 40, for example SiO₂, in FIG. 7 the electrically insulating structure 4 is formed by a plasma etching process, whereby the semiconductor material of the semiconductor layer sequence 1 has been electrically inactivated, i.e. is no longer suitable for conducting electrical current. In both FIG. 6 and FIG. 7, the electrically insulating structure 4 is at the same height as the optical structure 3 with respect to the active layer 10.

Both types of electrically insulating structure 4 can be used in all the exemplary embodiments described here.

In the exemplary embodiment of the semiconductor laser 100 shown in FIG. 8, unlike in the previous exemplary embodiments, the contacting is not realized via two opposing contact elements 80, 81, but rather both contact elements 80, 81 are contacted from the same side. This type of contacting is called top-side contacting.

FIG. 9 shows a position in a further exemplary embodiment of the method. The position shown in FIG. 9 essentially corresponds to the position of FIG. 3. Also here, a mask 20 made of a photoresist is applied to the side of the semiconductor layer sequence 1 facing away from the carrier substrate 2.

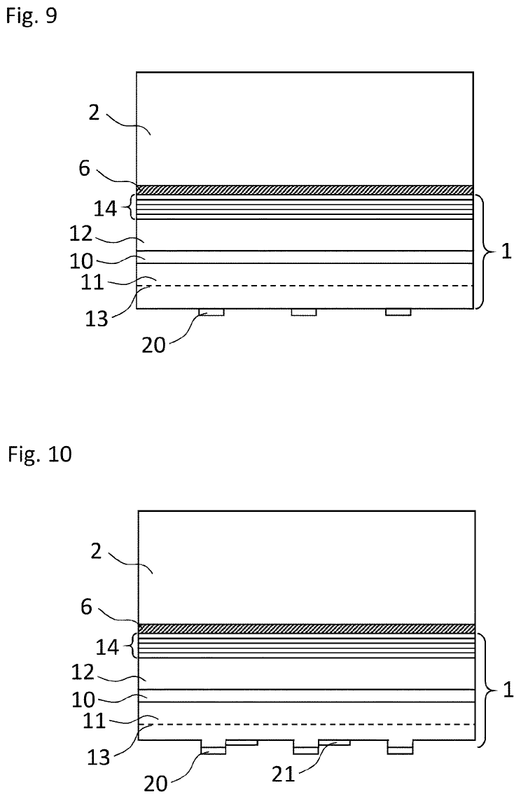

In the later position of FIG. 10, a first etching process has been carried out in which the areas of the semiconductor layer sequence 1 not covered by the mask 20 have been partially removed, but not up to the etch stop layer 13. Furthermore, in FIG. 10, a second mask 21 of photoresist has now been applied to the areas in which the semiconductor layer sequence 1 has been partially removed.

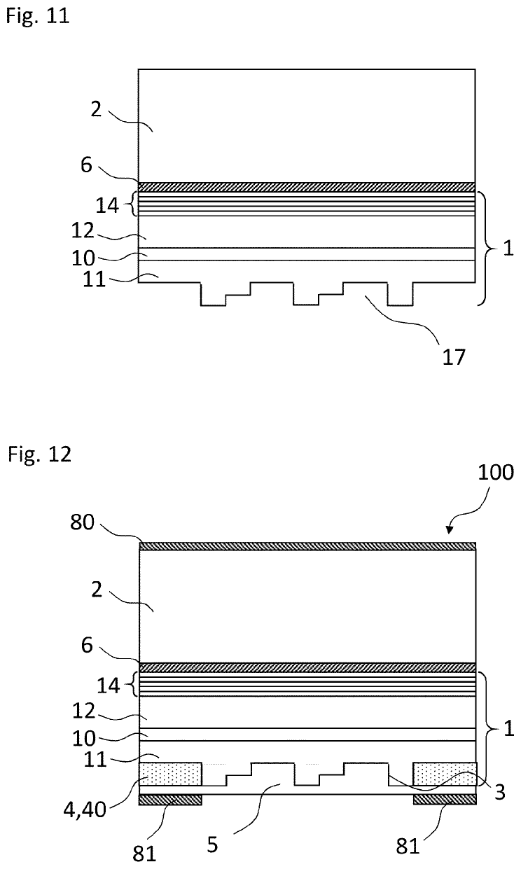

FIG. 11 shows a later position in the method, after a second etching process has been carried out. The areas of the semiconductor layer sequence 1 not covered by the masks 20, 21 have now been etched away up to the etch stop layer 13. The use of two masks and the two-stage etching process have resulted in depressions 17 with different depths.

FIG. 12 shows a position in the method after the semiconductor laser 100 has been completed. The depressions 17 are filled with TCO 5 as in the exemplary embodiment before, whereby the optical structure 3 is generated with a refractive index varying in the lateral direction. In addition, an electrically insulating structure 4 made of dielectric material 40 is again applied to the semiconductor layer sequence 1 in the edge region of the semiconductor layer sequence 1 in order to define an aperture of the semiconductor laser 100.

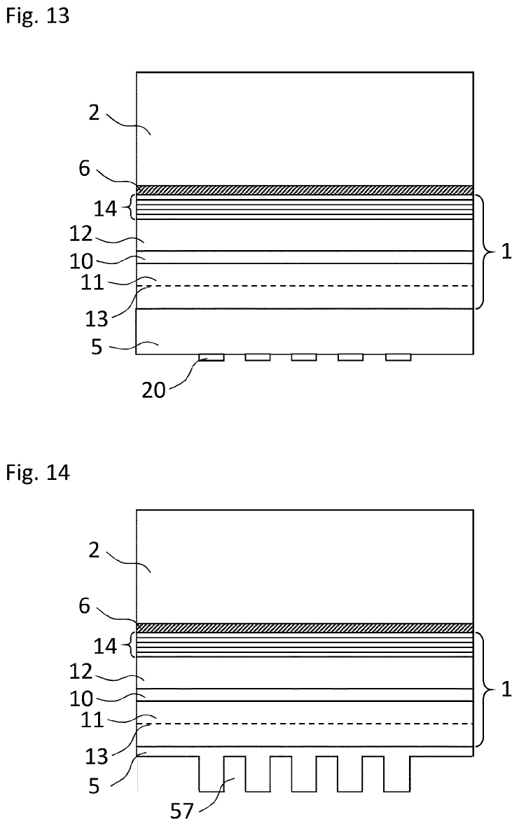

FIG. 13 shows a position in another exemplary embodiment of the method. The position shown in FIG. 13 follows, for example, the position of FIG. 2. After the growth substrate 16 has been removed, a layer of a TCO 5 has been applied to the semiconductor layer sequence 1 on a side facing away from the carrier substrate 2. A mask 20 of photoresist is applied to the side of this TCO layer 5 facing away from the semiconductor layer sequence 1.

FIG. 14 shows a position in the method where an etching process was used to etch away the areas of the TCO 5 that were free of the mask, resulting in depressions 57 in the TCO 5.

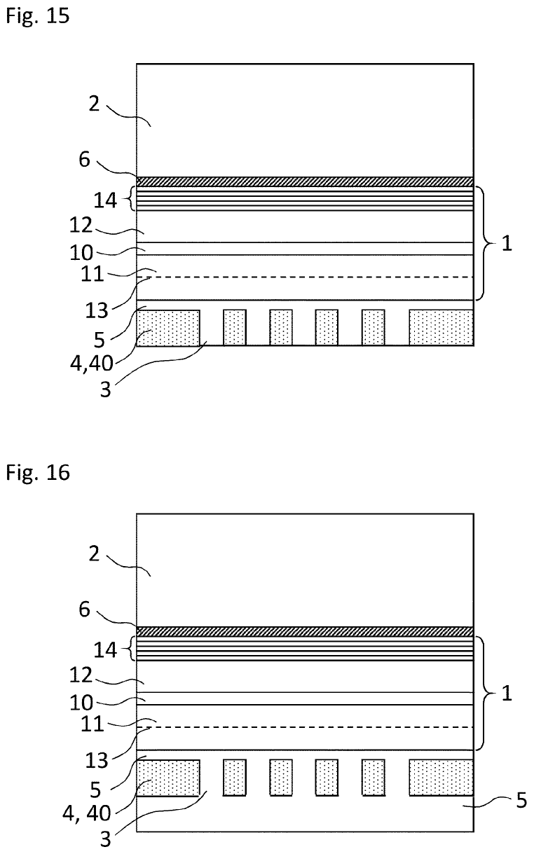

In the position shown in FIG. 15, the depressions 57 from FIG. 14 are filled with a dielectric material 40. The edge areas in which TCO 5 was removed have also been filled with dielectric material 40, once again creating the electrically insulating structure 4 to define the aperture.

Filling the depressions 57 in the TCO 5 with the dielectric material 40 has created an optical structure 3 with a refractive index that varies in the lateral direction. This is due in particular to the different refractive indices of the TCO 5 and the dielectric material 40 for the laser radiation.

FIG. 16 shows a position in which a further layer of the TCO 5 has been applied to the side of the dielectric material 40 facing away from the semiconductor layer sequence 1.

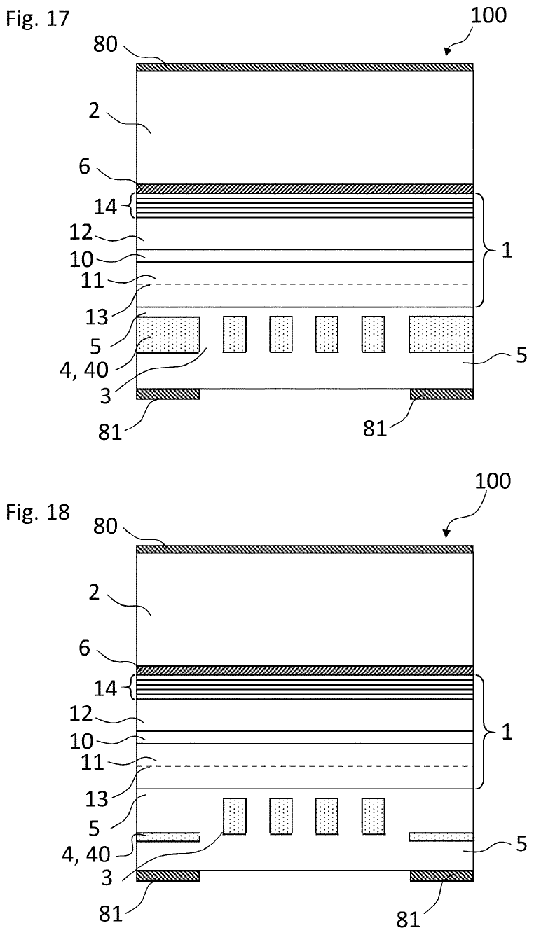

FIG. 17 shows the position of the method in which the semiconductor laser 100 is completed. Here again, contact elements 80,81 are applied to opposite sides of the semiconductor layer sequence 1 to make electrical contact.

FIG. 18 shows a further exemplary embodiment of the semiconductor laser 100. This exemplary embodiment differs from that of FIG. 17 in that here the electrically insulating structure 4 does not comprise the same thickness as the optical structure 3 and is also not at the same height as the optical structure 3 with respect to the active layer 10. Instead, the dielectric material 40 for forming the electrically insulating structure 4 is applied to areas of the TCO 5 that have not previously been thinned by an etching process. Such a configuration of the electrically insulating structure 4 is also conceivable in all other exemplary embodiments.

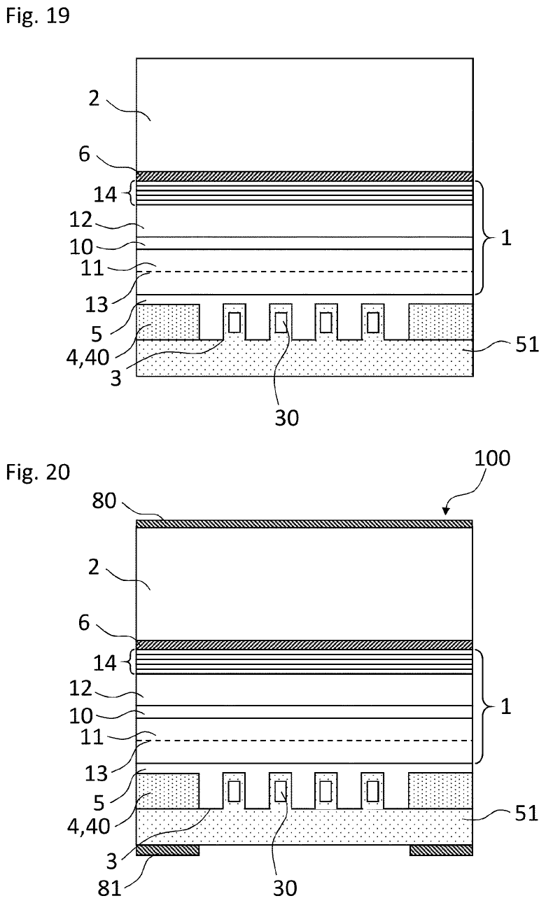

FIG. 19 shows a position in another exemplary embodiment of the method. This position follows, for example, the position of FIG. 14. Here, only the edge regions in which the TCO 5 was removed by the etching process were filled with the dielectric material 40 to form the electrically insulating structure 4. The depressions 57 in the TCO 5 were filled with another TCO 51 instead of a dielectric material, which is preferably different from the TCO 5 in terms of refractive index. In addition, the further TCO 51 was applied, for example, by a directional, i.e. non-conformal, deposition process, as a result of which the growth rate within the depressions 57 is different in the vertical direction than in the lateral direction. As a result, cavities 30 have been formed in the depressions 57. These cavities 30 form part of the optical structure 3 and are different with respect to the regions in between in terms of refractive index.

FIG. 20 shows a position of the method after completion of the semiconductor laser 100. Once again, contact elements 80, 81 are applied for electrical contacting.

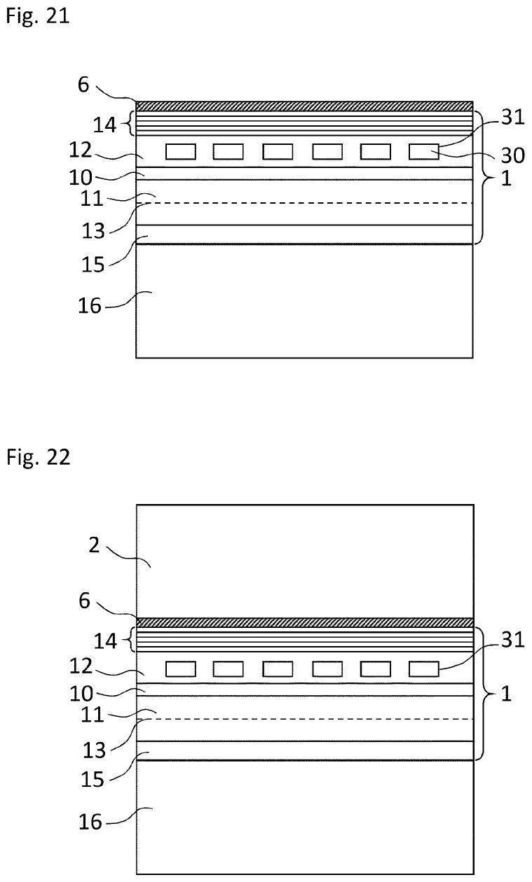

FIG. 21 shows a position in a further exemplary embodiment of the method. Here, a semiconductor layer sequence 1 has been grown on the growth substrate 16, with a further optical structure 31 already formed within the semiconductor layer sequence 1. The further optical structure 31 is formed between the Bragg mirror 14 and the active layer 10. This further optical structure 31 is formed, for example, by overgrowth of structures introduced into the semiconductor layer sequence 1 (regrowth). For example, the growth process was interrupted for this purpose, structures such as depressions or structures made of another material were then applied in or on the previously grown semiconductor layer sequence, and these structures were then overgrown with semiconductor material in a further growth process. The resulting cavities 30 create another optical structure 31 with a refractive index that varies in the lateral direction.

In the later position of FIG. 22, a carrier substrate 2 is applied to the side of the semiconductor layer sequence 1 facing away from the growth substrate 16 or to the metallic layer 6.

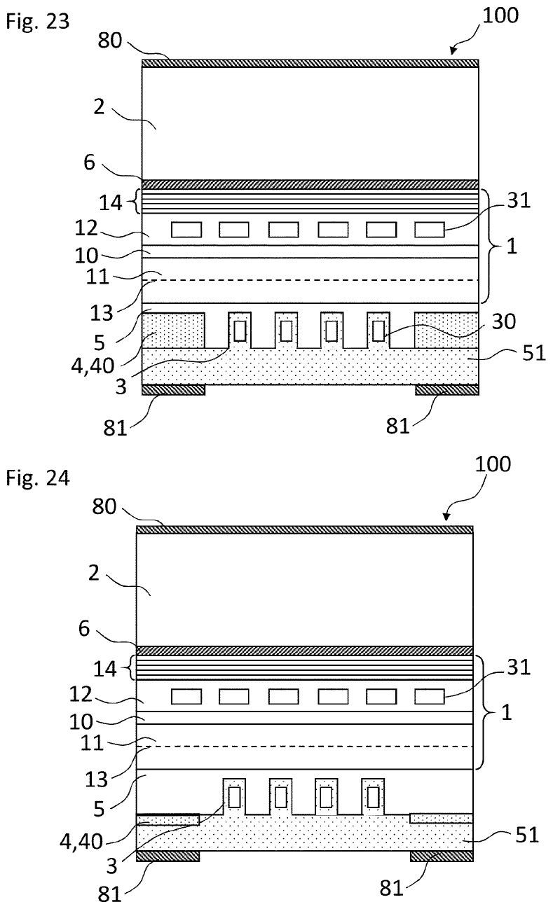

FIG. 23 shows a position in the method after completion of the semiconductor laser 100. In addition to the further optical structure 31 between the active layer 10 and the carrier substrate 2, an optical structure 3 has also been formed here on the side of the active layer 10 opposite the carrier substrate 2, as described in connection with FIGS. 19 and 20.

FIG. 24 shows an exemplary embodiment of the surface-emitting semiconductor laser 100 in which, unlike in FIG. 23, the electrically insulating structure 4 is again not formed at the height of the optical structure 3, but is arranged further away from the active layer 10 with respect to the active layer 10.

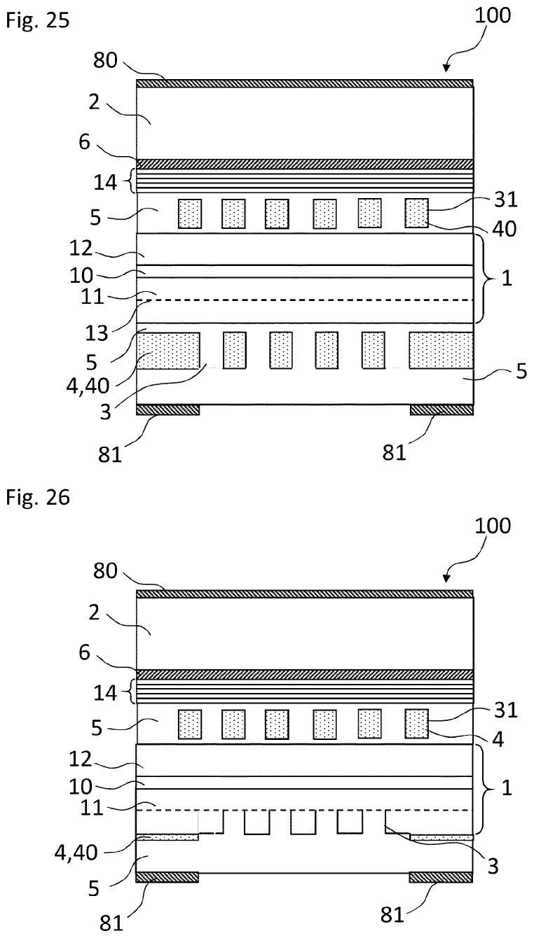

FIG. 25 shows an exemplary embodiment of the semiconductor laser 100 in which the further optical structure 31 between the carrier substrate 2 and the active layer 10 is not formed within the semiconductor layer sequence 1, but in a layer of TCO 5 arranged between the semiconductor layer sequence 1 and the carrier substrate 2. Here, regions of dielectric material 40 are arranged in the TCO layer 5.

In the exemplary embodiment of the semiconductor laser 100 of FIG. 26, the optical structure 3 on the side of the semiconductor layer sequence 1 facing away from the carrier substrate 2 is partially formed by semiconductor material of the semiconductor layer sequence 1, as described, for example, in connection with FIGS. 1 to 6.

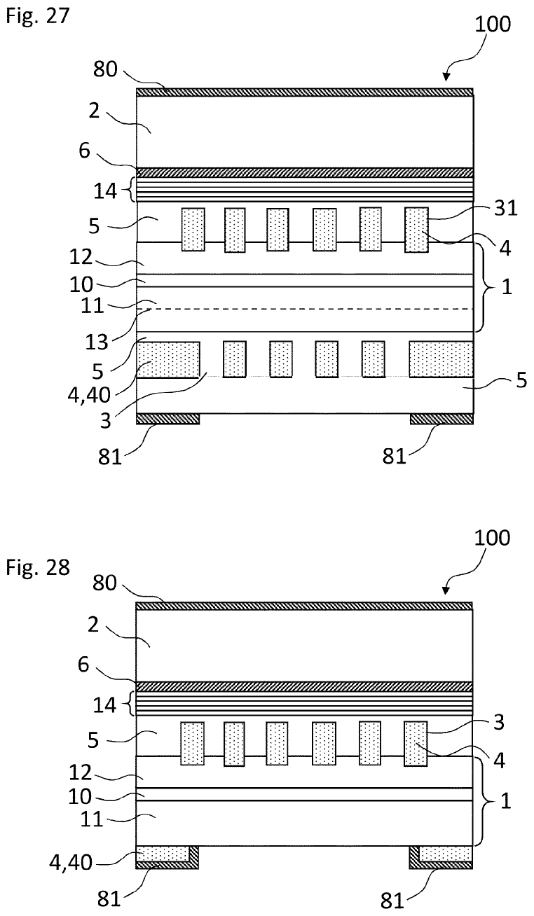

In the exemplary embodiment of the semiconductor laser 100 of FIG. 27, the further optical structure 31 between the carrier substrate 2 and the active layer 10 is formed neither exclusively in the TCO 5 nor in the semiconductor layer sequence 1, but in the transition region between the TCO 5 and the semiconductor layer sequence 1.

In the exemplary embodiment of FIG. 28, an optical structure 3 is formed only between the carrier substrate 2 and the active layer 10, but not on a side of the active layer 10 facing away from the carrier substrate 2. The optical structure 3 is formed here in the same way as the other optical structure 31 in FIG. 27.

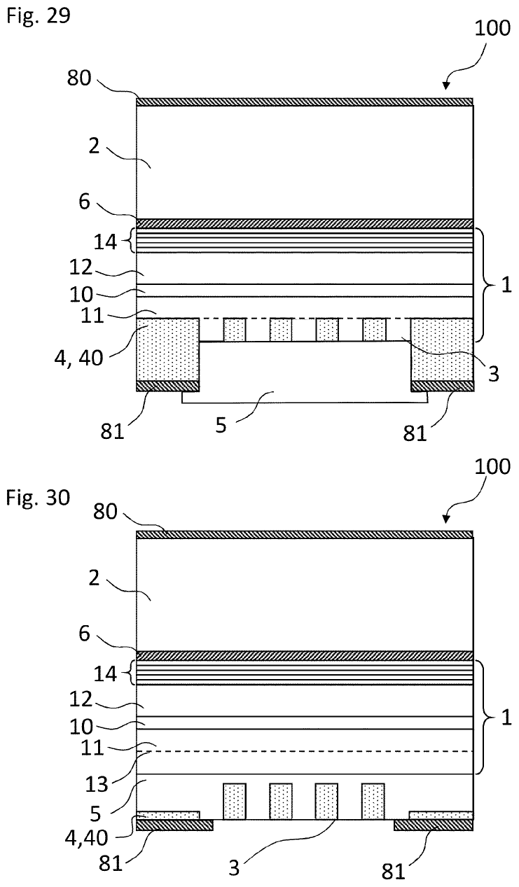

FIG. 29 shows an exemplary embodiment of the semiconductor laser 100, in which the optical structure 3 is formed by semiconductor material and dielectric material 40. In contrast to the description in connection with FIGS. 1 to 6, the depressions that were introduced into the semiconductor layer sequence 1 via the etching process were not filled with TCO 5 but with dielectric material 40. The dielectric material 40 was then ground back to the semiconductor layer sequence 1, for example, and a TCO 5 was then applied for contacting to the semiconductor material. Here, for example, the TCO 5 was not applied until after the contact elements 81 had been applied.

FIG. 30 again shows an exemplary embodiment of the semiconductor laser 100, in which the optical structure 3 is formed by juxtaposed regions of TCO 5 and dielectric material 40.

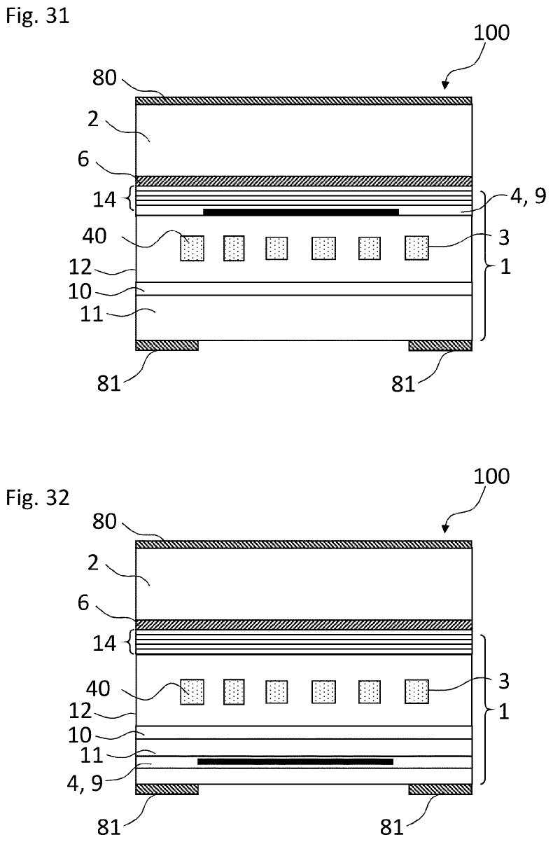

In the exemplary embodiment of FIG. 31, a semiconductor laser 100 is shown in which the aperture is not defined on the side of the active layer 10 facing away from the carrier substrate 2, but between the active layer 10 and the carrier substrate 2. For this purpose, the semiconductor layer sequence 1 comprises a metal-containing, e.g. aluminum-containing, layer 9 between the Bragg mirror 14 and the active layer 10. This aluminum-containing layer 9 is specifically oxidized in the edge region of the semiconductor layer sequence 1 in order to generate an electrically insulating structure 4, which defines the aperture of the semiconductor laser 100. In the interior of the semiconductor laser 100, i.e. laterally spaced from the side surfaces of the semiconductor laser 100, the aluminum-containing layer 9 is not oxidized so that there is electrical conductivity for the injection of charge carriers into the active layer 10.

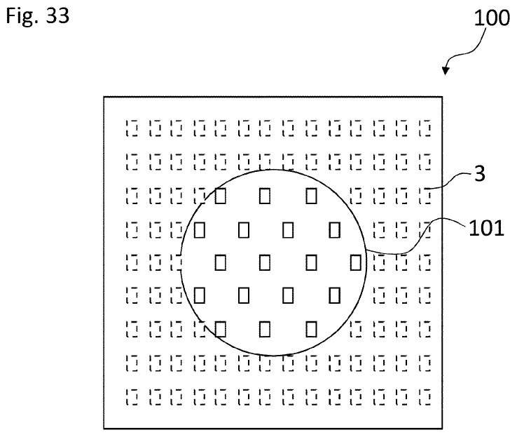

In the exemplary embodiment of the semiconductor laser 100 shown in FIG. 32, unlike in FIG. 31, the partially oxidized, aluminum-containing layer 9 is formed on a side of the active layer 10 facing away from the carrier substrate 2 in order to define the aperture of the semiconductor laser 100 there. The aluminum-containing layer 9 is, for example, AlAs or AlN.

FIG. 33 shows an exemplary embodiment of the semiconductor laser 100 in top view of the radiation exit surface. The aperture 101 can be seen, which is defined, for example, by the electrically insulating structure 4, but also by the arrangement of the contact element 81 (not shown for better clarity). It can also be seen that the optical structure 3 comprises a variation of the refractive index in the lateral direction, along the plane of the paper. The regions of a particular refractive index are shown here by the dashed boxes. The dashed boxes represent cavities, for example. The regions outside the dashed boxes comprise a different refractive index. Instead of the rectangular shape of the areas, any other shape is also conceivable, for example a round or oval shape.

In FIG. 33, the variation of the refractive index is periodic in the lateral direction. It can also be seen that the optical structure 3 is designed differently in the region of the aperture 101 than in the region outside the aperture 101. In the region outside the aperture 101, the optical structure 3 can thus fulfill different tasks than in the region of the aperture 101. For example, in the region outside the aperture 101, the optical structure 3 can be set up to deflect the laser radiation in the direction of the aperture 101 for high decoupling efficiency, whereas in the region of the aperture 101, the optical structure 3 can be configured for wavelength selection. In any case, FIG. 33 illustrates that the optical structure 3 is not limited to the area of the aperture 101, but extends laterally beyond the aperture 101, for example by more than 10 μm.

The invention is not limited to the exemplary embodiments by the description thereof. Rather, the invention includes any new feature as well as any combination of features, which includes in particular any combination of features in the patent claims, even if these features or this combination itself is not explicitly stated in the patent claims or exemplary embodiments.

1. A surface emitting semiconductor laser comprising:
a semiconductor layer sequence with an active layer for generating laser radiation,
a carrier substrate on one side of the semiconductor layer sequence, and
an optical structure for influencing at least one degree of freedom of the laser radiation, wherein
the carrier substrate is different from a growth substrate of the semiconductor layer sequence and the growth substrate is at least partially removed, and
the optical structure comprises a refractive index for the laser radiation that varies in lateral direction.

2. The surface-emitting semiconductor laser according to claim 1, wherein
the active layer is arranged between the carrier substrate and the optical structure.

3. The surface-emitting semiconductor laser according to claim 1, wherein
the optical structure comprises a photonic crystal.

4. The surface-emitting semiconductor laser according to claim 1, wherein
the optical structure is at least partially formed by the semiconductor material of the semiconductor layer sequence.

5. The surface-emitting semiconductor laser according to claim 1, wherein
the optical structure is at least partially formed by transparent conductive oxide, and/or
the optical structure is at least partially formed by dielectric material.

6. The surface-emitting semiconductor laser according to claim 1, wherein
the optical structure comprises a plurality of cavities.

7. The surface-emitting semiconductor laser according to claim 1, wherein
an electrically insulating structure for reducing a current impression in the semiconductor layer sequence is provided in the edge region of the semiconductor layer sequence, wherein generation of laser radiation is at least suppressed in the region of the electrically insulating structure.

8. The surface-emitting semiconductor laser according to claim 7, wherein the electrically insulating structure is arranged at the same height as the optical structure with respect to the active layer.

9. The surface-emitting semiconductor laser according to claim 1, wherein
a Bragg mirror is arranged between the carrier substrate and the active layer.

10. The surface-emitting semiconductor laser according to claim 1, wherein
the semiconductor layer sequence is based on AlₙIn₁₋ₙ₋ₘGaₘN or AlₙIn₁₋ₙ₋ₘGaₘAs with 0≤n≤1, 0≤m≤1 and m+n≤1,
the semiconductor layer sequence comprises a p-conducting layer between the active layer and the carrier substrate, and
the carrier substrate comprises one or more of the following materials: Si, Ge, ceramic, AlN, SiC, and sapphire.

11. The surface-emitting semiconductor laser according to claim 2, wherein
a further optical structure with a refractive index varying in the lateral direction is arranged between the active layer and the carrier substrate.

12. The surface-emitting semiconductor laser according to claim 1, wherein
a metal layer is arranged between the carrier substrate and the semiconductor layer sequence.

13. A method of manufacturing a surface-emitting semiconductor laser comprising:
growing a semiconductor layer sequence with an active layer on a growth substrate, wherein the active layer is configured to generate laser radiation,
applying a carrier substrate to a side of the semiconductor layer sequence facing away from the growth substrate,
at least partial removing the growth substrate from the semiconductor layer sequence, and
forming an optical structure on one side of the semiconductor layer sequence, wherein the optical structure comprises a refractive index for the laser radiation which varies in lateral direction, perpendicular to growth direction.

14. The method according to claim 13, wherein forming the optical structure comprises:
structuring the semiconductor layer sequence by introducing a plurality of depressions into the semiconductor layer sequence, and
filling the depressions with a transparent conductive oxide and/or a dielectric material.

15. The method according to claim 13, wherein forming the optical structure comprises:
applying a transparent conductive oxide to the semiconductor layer sequence, and
structuring the transparent conductive oxide by introducing depressions into the transparent conductive oxide.

16. The method according to claim 13, wherein the optical structure is formed by overgrowth of structures with semiconductor material in the semiconductor layer sequence.

17. A surface-emitting semiconductor laser comprising:
a semiconductor layer sequence with an active layer for generating laser radiation;
a carrier substrate on one side of the semiconductor layer sequence; and
an optical structure for influencing at least one degree of freedom of the laser radiation, wherein
the carrier substrate is different from a growth substrate of the semiconductor layer sequence and the growth substrate is at least partially removed,
the optical structure comprises a refractive index for the laser radiation that varies in lateral direction,
the optical structure is a photonic crystal, and
the optical structure is at least partially formed by transparent conductive oxide.
